(19) United States
(12) Patent Application Publication
(10) Pub. No.: US 2023/0380250 A1
(43) Pub. Date: Nov. 23, 2023

(54) DISPLAY DEVICE AND MANUFACTURING METHOD THEREOF

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Zeyu Li, Beijing (CN); Mingjiong Zhang, Beijing (CN); Hao Yan, Beijing (CN); Taofeng Xie, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/027,756

(22) PCT Filed: Mar. 4, 2022
(86) PCT No.: PCT/CN2022/079289

§ 371 Date: Mar. 22, 2023

(30) Foreign Application Priority Data
Jun. 29, 2021 (CN) 202110724593.6

(51) Int. Cl. H10K 59/80; H10K 59/40; G02B 5/30

(52) U.S. Cl. CPC H10K 59/8791; H10K 59/40; G02B 5/3016

(57) ABSTRACT

The present disclosure provides a display device and a manufacturing method thereof, falling within the field of display technology. The display device includes: a display panel; a polarization module located on a light-emitting side of the display panel, where the polarization module includes a phase retardation layer and a linear polarization layer arranged in sequence along a direction away from the display panel; the display panel is reused as a substrate of the polarization module, or a touch panel located between the display panel and the polarization module is reused as the substrate of the polarization module. The present disclosure can reduce the thickness of the display device.

The present application claims the priority of Chinese Patent Application No. 202110724593.6 filed in China on Jun. 29, 2021, the entire contents of which are incorporated hereby by reference.

### TECHNICAL FIELD

The present disclosure relates to the field of display technology, in particular to a display device and a manufacturing method thereof.

### BACKGROUND

OLED (Organic Light-Emitting Diode, referred to as OLED) display devices have been listed as the most promising next-generation display technology due to their advantages such as thin, light, wide viewing angle, active light emission, continuously adjustable emission color, low cost, fast response, low power consumption, low driving voltage, wide operating temperature range, simple production process, high light emission efficiency and flexible display.

In the existing OLED display device, the polarizer, as a separate component, is integrated with the display panel or the touch panel through an adhesive material, which increases the thickness of the OLED display device, and is not conducive to the realization of flexibility and ultra-thinness.

### SUMMARY

The present disclosure aims to solve the technical problems, and provides a display device and a manufacturing method thereof, which can reduce the thickness of the display device.

In order to solve the above technical problems, the embodiments of the present disclosure provide the following technical solutions.

In one aspect, the display device is provided, including:
a display panel;
a polarization module located on a light-emitting side of the display panel, where the polarization module includes a phase retardation layer and a linear polarization layer arranged in sequence along a direction away from the display panel;
the display panel is reused as a substrate of the polarization module, or, a touch panel located between the display panel and the polarization module is reused as the substrate of the polarization module.

In some embodiments, the phase retardation layer is in direct contact with the linear polarization layer; or
an interlayer dielectric layer is arranged between the phase retardation layer and the linear polarization layer; or
a bonding adhesive layer is arranged between the phase retardation layer and the linear polarization layer.

In some embodiments, the display panel is reused as the substrate of the polarization module,
the phase retardation layer is in direct contact with the display panel; or
an interlayer dielectric layer is arranged between the phase retardation layer and the display panel; or
a bonding adhesive layer is arranged between the phase retardation layer and the display panel.

In some embodiments, the display panel is reused as the substrate of the polarization module, and the display device further includes:
a touch panel located at a side of the polarization module away from the display panel.

In some embodiments, the touch panel is reused as the substrate of the polarization module;
the phase retardation layer is in direct contact with the touch panel; or
an interlayer dielectric layer is arranged between the phase retardation layer and the touch panel; or
a bonding adhesive layer is arranged between the phase retardation layer and the touch panel.

In some embodiments, the polarization module further includes:
an encapsulation film located on a side of the linear polarization layer away from the phase retardation layer.

In some embodiments, the encapsulation film is in direct contact with the linear polarization layer; or
an interlayer dielectric layer is arranged between the encapsulation film and the linear polarization layer; or
a bonding adhesive layer is arranged between the encapsulation film and the linear polarization layer.

In some embodiments, the thickness of the interlayer dielectric layer is not more than 500 nm.

The embodiments of the present disclosure also provide a method for manufacturing a display device, including:
providing a display panel;
forming a polarization module on the display panel, or forming the polarization module on a touch panel on alight-emitting side of the display panel, where the polarization module includes a phase retardation layer and a linear polarization layer arranged in sequence along a direction away from the touch panel.

In some embodiments, forming the polarization module includes:
forming the phase retardation layer, and directly forming the linear polarization layer on the phase retardation layer; or
forming the phase retardation layer, forming an interlayer dielectric layer on the phase retardation layer, and forming the linear polarization layer on the interlayer dielectric layer; or
forming the phase retardation layer, forming a bonding adhesive layer on the phase retardation layer, and forming the linear polarization layer on the bonding adhesive layer.

In some embodiments, forming a polarization module on the display panel includes:
directly forming the phase retardation layer on the display panel; or
forming an interlayer dielectric layer on the display panel, and forming the phase retardation layer on the interlayer dielectric layer; or
forming a bonding adhesive layer on the display panel, and forming the phase retardation layer on the bonding adhesive layer.

In some embodiments, forming a polarization module on the touch panel includes:
directly forming the phase retardation layer on the touch panel; or
forming an interlayer dielectric layer on the touch panel, and forming the phase retardation layer on the interlayer dielectric layer; or
forming a bonding adhesive layer on the touch panel, and forming the phase retardation layer on the bonding adhesive layer.

In some embodiments, forming the polarization module further includes:
forming an encapsulation film on a side of the linear polarization layer away from the phase retardation layer.

In some embodiments, forming the encapsulation film includes:
directly forming the encapsulation film on the linear polarization layer; or
forming an interlayer dielectric layer on the linear polarization layer, and forming the encapsulation film on the interlayer dielectric layer; or

forming a bonding adhesive layer on the linear polarization layer, and forming the encapsulation film on the bonding adhesive layer.

### BRIEF DESCRIPTION OF THE DRAWINGS

FIG. 1 and FIG. 2 are schematic structural diagrams of an existing display device with integrated touch function;

FIG. 3 is a schematic structural diagram of the existing polarization module;

FIGS. 4-5 are schematic structural diagrams of the display device according to the embodiments of the present disclosure; and

FIGS. 6-15 are schematic structural diagrams of the polarization module according to the embodiments of the present disclosure.

### REFERENCE NUMBERS

01 Bonding adhesive layer
02 Phase retardation layer
03 Linear polarization layer
04 Substrate
05 Interlayer dielectric layer
06 Encapsulation film
07 Display panel
08 Touch panel
09 Polarization module

### DETAILED DESCRIPTION

In order to make the technical problems, technical solutions, and advantages to be solved by the embodiments of the present disclosure clearer, the following will be described in detail with the attached drawings and specific embodiments.

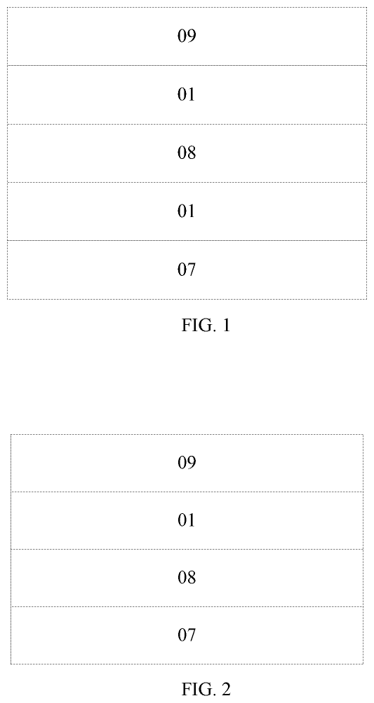

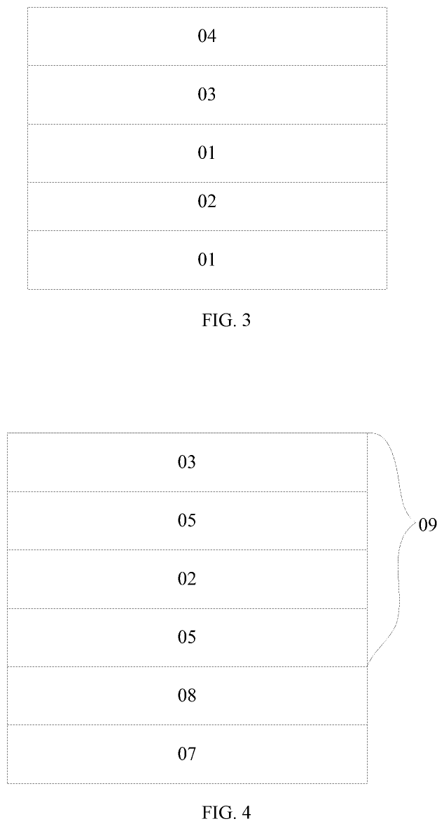

As shown in FIG. 1, an existing display device with integrated touch function includes a display panel 07, a touch panel 08, and a polarization module 09 which are laminated sequentially. The display panel 07 and the touch panel 08 are combined through a bonding adhesive layer 01, and the polarization module 09 and the touch panel 08 are combined through the bonding adhesive layer 01. Or, as shown in FIG. 2, the display device with integrated touch function includes a display panel 07, a touch panel 08, and a polarization module 09 which are laminated sequentially. The display panel 07 and the touch panel 08 are integrated, and the polarization module 09 and the touch panel 08 are combined through the bonding adhesive layer 01. As shown in FIG. 3, the polarization module 09 includes a substrate 04, a phase retardation layer 02, and a linear polarization layer 03 which are laminated sequentially. The material of the substrate 04 can be acrylic, cellulose triacetate film TAC or an optical material COP; the linear polarization layer 03 is formed on the substrate 04, the phase retardation layer 02 and the linear polarization layer 03 are combined through the bonding adhesive layer 01, and the bonding adhesive layer 01 is arranged on the phase retardation layer 02 for bonding with a touch panel.

It can be seen that the polarization module 09, as a separate component, is bonded and integrated with the touch panel through the bonding adhesive layer 01; the substrate of the polarization module 09 and the bonding adhesive layer 01 cannot be removed due to the manufacturing process; and the presence of the substrate of the polarization module 09 and the bonding adhesive layer 01 increases the thickness of the display device, which is not conducive to the realization of flexibility and ultra-thinness.

The embodiments of the present disclosure provide a display device and a manufacturing method thereof, which can reduce the thickness of the display device.

The embodiment of the present disclosure provides a display device, including:
a display panel;
a polarization module located on a light-emitting side of the display panel, where the polarization module includes a phase retardation layer and a linear polarization layer arranged in sequence along a direction away from the display panel;
the display panel is reused as the substrate of the polarization module, or, a touch panel located between the display panel and the polarization module is reused as the substrate of the polarization module.

In the embodiment, the polarization module is directly made on the display panel or the touch panel, so that the bonding adhesive layer between the polarization module and the display panel or the touch panel and the substrate of the polarization module can be omitted, the thickness of the display device can be reduced, which is conducive to the realization of flexibility and ultra-thinness, and the bent of the display device.

The display device includes, but is not limited to: a radio frequency unit, a network module, an audio output unit, an input unit, a sensor, a display unit, a user input unit, an interface unit, a memory, a processor, and a power supply, etc. It will be appreciated by those skilled in the art that the structure of the above display device does not constitute a limitation on the display device, and the display device can include more components or less components, or combine some components, or have different component arrangements. In the embodiments of the present disclosure, the display device includes, but is not limited to, a display, a mobile phone, a tablet computer, a television, a wearable electronic equipment, a navigation display equipment, etc.

The display device can be a television, a monitor, a digital photo frame, a mobile phone, a tablet computer and other products or components with display function. The display device further includes a flexible printed circuit board, a printed circuit board, and a backplane.

In the embodiment, the display panel may be reused as the substrate of the polarization module, that is, the polarization module is directly made on the outermost structure of the light-emitting side of the display panel; if the display panel is encapsulated by an encapsulation cover plate, the outermost structure of the light-emitting side of the display panel is the encapsulation cover plate; and if the display panel is encapsulated by a film, the outermost structure of the light-emitting side of the display panel is the encapsulation film.

In the embodiment, the touch panel may also be reused as the substrate of the polarization module, that is, the polarization module is directly made on the structure of the touch panel closest to the polarization module, and the structure of the touch panel closest to the polarization module can be the encapsulation cover plate, a flat layer, or the encapsulation film.

In the embodiment, for the interior of the polarization module 09, the phase retardation layer 02 can be combined with the linear polarization layer 03 by naturally attaching or adding the interlayer dielectric layer, because the interlayer dielectric layer is generally made of inorganic insulating material, and the film thickness is in the range of tens of nm to hundreds of nm, which is much less than the thickness of the bonding adhesive layer 01; therefore, the thickness of the polarization module 09 can be reduced, and the flexibility and ultra-thinness of the polarization module 09 can be realized.

In some embodiments, as shown in FIG. 7, the phase retardation layer 02 is in direct contact with the linear polarization layer 03; or, as shown in FIGS. 4-6, an interlayer dielectric layer 05 is arranged between the phase retardation layer 02 and the linear polarization layer 03, which are combined through the interlayer dielectric layer 05. The thickness of the interlayer dielectric layer 05 cannot be more than 500 nm, such as 10-50 nm, and the interlayer dielectric layer 05 can be an organic or inorganic compound with a polarity between the linear polarization layer 03 and the phase retardation layer 02.

Certainly, a bonding adhesive layer 01 can also be arranged between the phase retardation layer 02 and the linear polarization layer 03, which are combined through the bonding adhesive layer 01.

In the embodiment, if the display panel is reused as the substrate of the polarization module, the phase retardation layer 02 can be combined with the display panel by naturally attaching or adding the interlayer dielectric layer, because the interlayer dielectric layer is generally made of inorganic insulating material, and the film thickness is between tens of nm and hundreds of nm, which is much less than the thickness of the bonding adhesive layer 01; therefore, the thickness of the display device can be reduced.

In some embodiments, the phase retardation layer can be in direct contact with the display panel; or an interlayer dielectric layer is arranged between the phase retardation layer and the display panel. The thickness of the interlayer dielectric layer 05 cannot be more than 500 nm.

Certainly, a bonding adhesive layer can also be arranged between the phase retardation layer 02 and the display panel, which are combined through the bonding adhesive layer 01.

In some embodiments, the display panel is reused as the substrate of the polarization module, and the display device further includes:
a touch panel located at a side of the polarization module away from the display panel.

In the embodiment, if the touch panel is reused as the substrate of the polarization module, the phase retardation layer 02 can be combined with the touch panel by naturally attaching or adding the interlayer dielectric layer, because the interlayer dielectric layer is generally made of inorganic insulating material, and the film thickness is between tens of nm and hundreds of nm, which is much less than the thickness of the bonding adhesive layer 01; therefore, the thickness of the display device can be reduced.

In some embodiments, the phase retardation layer can be in direct contact with the touch panel; or an interlayer dielectric layer is arranged between the phase retardation layer and the touch panel. The thickness of the interlayer dielectric layer 05 cannot be not more than 500 nm.

Certainly, a bonding adhesive layer can also be arranged between the phase retardation layer 02 and the touch panel, which are combined through the bonding adhesive layer 01.

In a specific example, as shown in FIG. 4, the display device includes a display panel 07, a touch panel 08, and a polarization module 09 which are laminated sequentially. The polarization module 09 includes a linear polarization layer 03, an interlayer dielectric layer 05, a phase retardation layer 02, and an interlayer dielectric layer 05 which are laminated sequentially; the polarization module 09 is located above the touch panel 08, and is combined with the display panel 08 through the interlayer dielectric layer 05; certainly, the polarization module 09 can also be combined with the display panel 08 by naturally attaching; inside the polarization module 09, the linear polarization layer 03 and the phase retardation layer 02 are combined through the interlayer dielectric layer 05; certainly, the linear polarization layer 03 and the phase retardation layer 02 can also be combined by naturally attaching, and no substrate is not arranged on the linear polarization layer 03, so that the thickness of the display device can be greatly reduced. The thickness of the interlayer dielectric layer cannot be more than 500 nm.

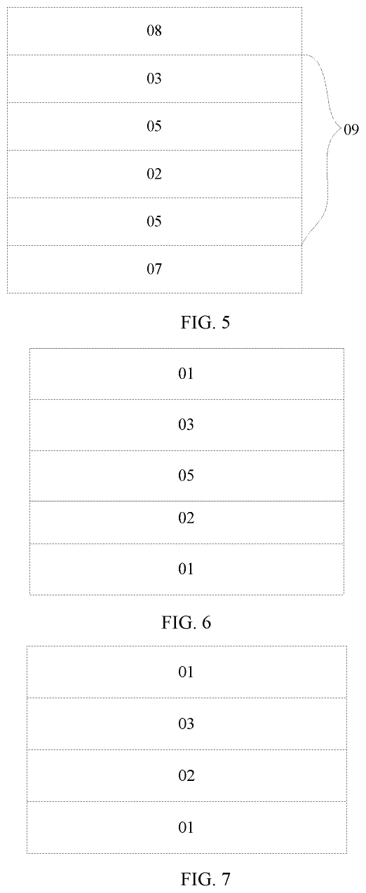

In a specific example, as shown in FIG. 5, the display device includes a display panel 07, a polarization module 09, and a touch panel 08 which are laminated sequentially. The polarization module 09 includes a linear polarization layer 03, an interlayer dielectric layer 05, a phase retardation layer 02, and an interlayer dielectric layer 05 which are laminated sequentially; the polarization module 09 is located above the display panel 07, and is combined with the display panel 07 through the interlayer dielectric layer 05; certainly, the polarization module 09 can also be combined with the display panel 07 by naturally attaching; inside the polarization module 09, the linear polarization layer 03 and the phase retardation layer 02 are combined through the interlayer dielectric layer 05; certainly, the linear polarization layer 03 and the phase retardation layer 02 can also be combined by naturally attaching, and no substrate is not arranged on the linear polarization layer 03, which is in direct contact with the touch panel 08, so that the thickness of the display device can be greatly reduced. The thickness of the interlayer dielectric layer cannot be more than 500 nm.

In a specific example, as shown in FIG. 6, the polarization module 09 includes a bonding adhesive layer 01, a linear polarization layer 03, an interlayer dielectric layer 05, a phase retardation layer 02, and a bonding adhesive layer 01 which are laminated sequentially. The linear polarization layer 03 and the phase retardation layer 02 are combined the interlayer dielectric layer 05, which is used to replace the bonding adhesive layer 01, no substrate is arranged on the linear polarization layer 03, and the bonding adhesive layer 01 is used to replace the substrate, which can greatly reduce the thickness of the display device. The thickness of the interlayer dielectric layer cannot be more than 500 nm.

In a specific example, as shown in FIG. 7, the polarization module 09 includes a bonding adhesive layer 01, a linear polarization layer 03, a phase retardation layer 02 and a bonding adhesive layer 01 which are laminated sequentially. The linear polarization layer 03 and the phase retardation layer 02 are combined by naturally attaching. No bonding adhesive layer 01 is arranged between the linear polarization layer 03 and the phase retardation layer 02, no substrate is arranged on the linear polarization layer 03, and the bonding adhesive layer 01 is used to replace the substrate, so that the thickness of the display device can be greatly reduced

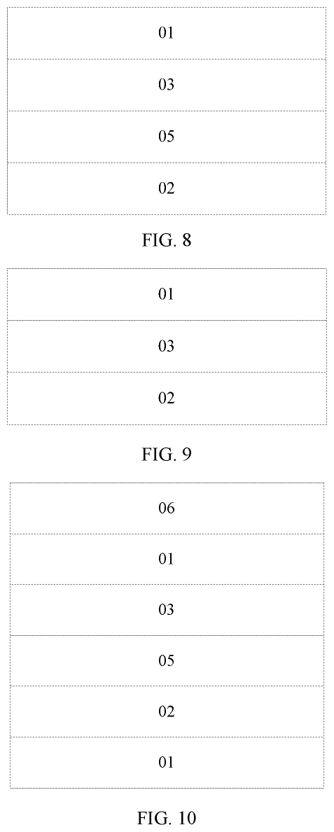

In a specific example, as shown in FIG. 8, the polarization module 09 includes a bonding adhesive layer 01, a linear polarization layer 03, an interlayer dielectric layer 05, and a phase retardation layer 02 which are laminated sequentially. The linear polarization layer 03 and the phase retardation layer 02 are combined through the interlayer dielectric layer 05, which is used to replace the bonding adhesive layer 01, no substrate is arranged on the linear polarization layer 03, and the bonding adhesive layer 01 is used to replace the substrate, which can greatly reduce the thickness of the display device. The thickness of the interlayer dielectric layer cannot be more than 500 nm.

In a specific example, as shown in FIG. 9, the polarization module 09 includes a bonding adhesive layer 01, a linear polarization layer 03, and a phase retardation layer 02 which are laminated sequentially. The linear polarization layer 03 and the phase retardation layer 02 are combined by naturally attaching. No substrate is arranged on the linear polarization layer 03, and the bonding adhesive layer 01 is used to replace the substrate, so that the thickness of the display device can be greatly reduced.

In the relevant art, the display device further includes the encapsulation film, and the encapsulation film and the polarization module 09, as two independent components, are bonded to the display panel or the touch panel respectively through two bonding processes, which increases the process difficulty and reduces the product yield.

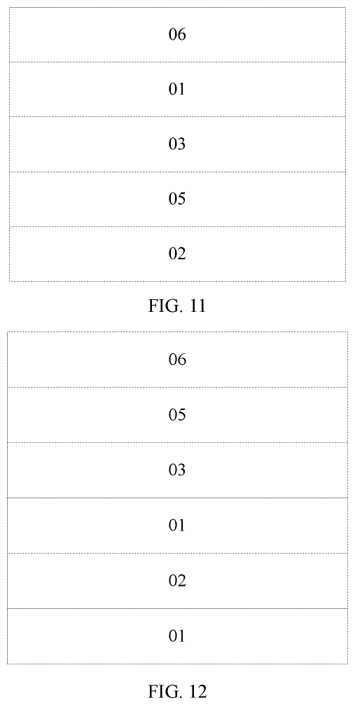

In the embodiment, the integration of the encapsulation film and the polarization module 09 can simplify the bonding process of the display device, improve the product yield and shorten the production cycle. As shown in FIGS. 10-15, the polarization module further includes:

an encapsulation film 06 located on a side of the linear polarization layer 03 away from the phase retardation layer 02.

In the embodiment, for the interior of the polarization module 09, the encapsulation film 06 and the linear polarization layer 03 can be combined by naturally attaching or adding the interlayer dielectric layer, because the interlayer dielectric layer is generally made of inorganic insulating material, and the film thickness is between tens of nm and hundreds of nm, which is much less than the thickness of the bonding adhesive layer 01; therefore, the thickness of the polarization module 09 can be reduced, and the flexibility and ultra-thinness of the polarization module 09 can be realized.

Certainly, a bonding adhesive layer 01 can also be arranged between the encapsulation film 06 and the linear polarization layer 03, which are combined through the bonding adhesive layer 01.

In a specific example, as shown in FIG. 10, the polarization module 09 includes a bonding adhesive layer 01, a phase retardation layer 02, an interlayer dielectric layer 05, a linear polarization layer 03, a bonding adhesive layer 01, and an encapsulation film 06 which are laminated sequentially; inside the polarization module 09, the linear polarization layer 03 and the phase retardation layer 02 are combined through the interlayer dielectric layer 05, no substrate is arranged on the linear polarization layer 03, which is combined with the encapsulation film 06 through the bonding adhesive layer 01, so that the thickness of the polarization module 09 can be greatly reduced. The thickness of the interlayer dielectric layer cannot be more than 500 nm. Certainly, it is also possible to bind the linear polarization layer 03 with the phase retardation layer 02 by naturally attaching.

In a specific example, as shown in FIG. 11, the polarization module 09 includes a phase retardation layer 02, an interlayer dielectric layer 05, a linear polarization layer 03, a bonding adhesive layer 01, and an encapsulation film 06 which are laminated sequentially; inside the polarization module 09, the linear polarization layer 03 and the phase retardation layer 02 are combined through the interlayer dielectric layer 05, no substrate is arranged on the linear polarization layer 03, which is combined with the encapsulation film 06 through the bonding adhesive layer 01, so that the thickness of the polarization module 09 can be greatly reduced. The thickness of the interlayer dielectric layer cannot be more than 500 nm. Certainly, it is also possible to bind the linear polarization layer 03 with the phase retardation layer 02 by naturally attaching.

In a specific example, as shown in FIG. 12, the polarization module 09 includes a bonding adhesive layer 01, a phase retardation layer 02, a bonding adhesive layer 01, a linear polarization layer 03, an interlayer dielectric layer 05, and an encapsulation film 06 which are laminated sequentially; inside the polarization module 09, the linear polarization layer 03 and the encapsulation film 06 are combined through the interlayer dielectric layer 05; and no substrate is not arranged on the linear polarization layer 03, so that the thickness of the polarization module 09 can be greatly reduced. The thickness of the interlayer dielectric layer cannot be more than 500 nm. The polarization module 09 can be adhered to the display panel or the touch panel through the bonding adhesive layer 01.

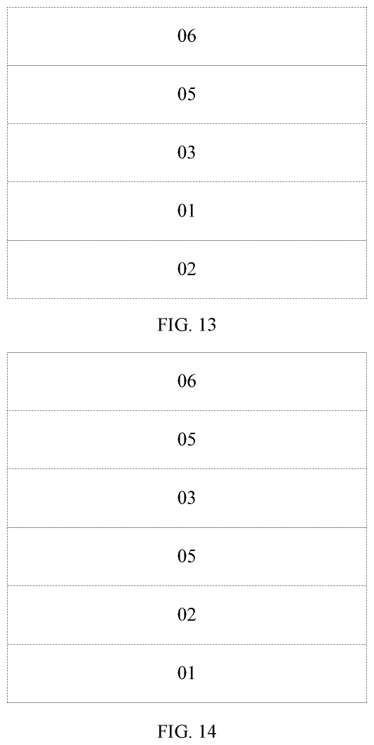

In a specific example, as shown in FIG. 13, the polarization module 09 includes a phase retardation layer 02, a bonding adhesive layer 01, a linear polarization layer 03, an interlayer dielectric layer 05, and an encapsulation film 06 which are laminated sequentially; inside the polarization module 09, the linear polarization layer 03 and the encapsulation film 06 are combined through the interlayer dielectric layer 05; and no substrate is not arranged on the linear polarization layer 03, so that the thickness of the polarization module 09 can be greatly reduced. The thickness of the interlayer dielectric layer cannot be more than 500 nm.

In a specific example, as shown in FIG. 14, the polarization module 09 includes a bonding adhesive layer 01, a phase retardation layer 02, an interlayer dielectric layer 05, a linear polarization layer 03, an interlayer dielectric layer 05, and an encapsulation film 06 which are laminated sequentially; inside the polarization module 09, the linear polarization layer 03 and the phase retardation layer 02 are combined through the interlayer dielectric layer 05, the linear polarization layer 03 and the encapsulation film 06 are combined through the interlayer dielectric layer 05, and no substrate is not arranged on the linear polarization layer 03, so that the thickness of the polarization module 09 can be greatly reduced. The thickness of the interlayer dielectric layer cannot be more than 500 nm. The polarization module 09 can be adhered to the display panel or the touch panel through the bonding adhesive layer 01.

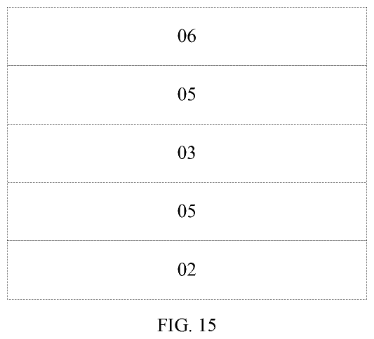

In a specific example, as shown in FIG. 15, the polarization module 09 includes a phase retardation layer 02, an interlayer dielectric layer 05, a linear polarization layer 03, an interlayer dielectric layer 05, and an encapsulation film 06 which are laminated sequentially; inside the polarization module 09, the linear polarization layer 03 and the phase retardation layer 02 are combined through the interlayer dielectric layer 05, the linear polarization layer 03 and the encapsulation film 06 are combined through the interlayer dielectric layer 05, and no substrate is not arranged on the linear polarization layer 03, so that the thickness of the polarization module 09 can be greatly reduced. The thickness of the interlayer dielectric layer cannot be more than 500 nm.

In the embodiment, the phase retardation layer 02, the interlayer dielectric layer 05, and the linear polarization layer 03 can be prepared by a coating process; specifically, the phase retardation layer 02 and the linear polarization layer 03 can be made of liquid crystal materials.

The embodiments of the present disclosure also provide a method for manufacturing a display device, including:
providing a display panel;
forming a polarization module on the display panel, or forming the polarization module on a touch panel on alight-emitting side of the display panel, where the polarization module includes a phase retardation layer and a linear polarization layer arranged in sequence along a direction away from the touch panel.

In the embodiment, the polarization module is directly made on the display panel or the touch panel, so that the bonding adhesive layer between the polarization module and the display panel or the touch panel and the substrate of the polarization module can be omitted, the thickness of the display device can be reduced, which is conducive to the realization of flexibility and ultra-thinness, and the bent of the display device.

In the embodiment, the display panel may be reused as the substrate of the polarization module, that is, the polarization module is directly made on the outermost structure of the light-emitting side of the display panel; if the display panel is encapsulated by an encapsulation cover plate, the outermost structure of the light-emitting side of the display panel is the encapsulation cover plate; and if the display panel is encapsulated by a film, the outermost structure of the light-emitting side of the display panel is the encapsulation film.

In the embodiment, the touch panel may also be reused as the substrate of the polarization module, that is, the polarization module is directly made on the structure of the touch panel closest to the polarization module, and the structure of the touch panel closest to the polarization module can be the encapsulation cover plate, a flat layer, or the encapsulation film.

In the embodiment, for the interior of the polarization module 09, the phase retardation layer 02 can be combined with the linear polarization layer 03 by naturally attaching or adding the interlayer dielectric layer, because the interlayer dielectric layer is generally made of inorganic insulating material, and the film thickness is between tens of nm and hundreds of nm, which is much less than the thickness of the bonding adhesive layer 01; therefore, the thickness of the polarization module 09 can be reduced, and the flexibility and ultra-thinness of the polarization module 09 can be realized.

In some embodiments, as shown in FIG. 7, the phase retardation layer 02 is in direct contact with the linear polarization layer 03; or, as shown in FIGS. 4-6, an interlayer dielectric layer 05 is arranged between the phase retardation layer 02 and the linear polarization layer 03, which are combined through the interlayer dielectric layer 05. The thickness of the interlayer dielectric layer 05 cannot be more than 500 nm.

Certainly, a bonding adhesive layer 01 can also be arranged between the phase retardation layer 02 and the linear polarization layer 03, which are combined through the bonding adhesive layer 01.

In some embodiments, forming the polarization module includes:
forming the phase retardation layer, and directly forming the linear polarization layer on the phase retardation layer; or
forming the phase retardation layer, forming an interlayer dielectric layer on the phase retardation layer, and forming the linear polarization layer on the interlayer dielectric layer; or
forming the phase retardation layer, forming a bonding adhesive layer on the phase retardation layer, and forming the linear polarization layer on the bonding adhesive layer.

In the embodiment, if the display panel is reused as the substrate of the polarization module, the phase retardation layer 02 can be combined with the display panel by naturally attaching or adding the interlayer dielectric layer, because the interlayer dielectric layer is generally made of inorganic insulating material, and the film thickness is between tens of nm and hundreds of nm, which is much less than the thickness of the bonding adhesive layer 01; therefore, the thickness of the display device can be reduced.

In some embodiments, the phase retardation layer can be in direct contact with the display panel; or an interlayer dielectric layer is arranged between the phase retardation layer and the display panel. The thickness of the interlayer dielectric layer 05 cannot be more than 500 nm.

Certainly, a bonding adhesive layer can also be arranged between the phase retardation layer 02 and the display panel, which are combined through the bonding adhesive layer 01.

In some embodiments, forming a polarization module on the display panel includes:
directly forming the phase retardation layer on the display panel; or
forming an interlayer dielectric layer on the display panel, and forming the phase retardation layer on the interlayer dielectric layer; or
forming a bonding adhesive layer on the display panel, and forming the phase retardation layer on the bonding adhesive layer.

In the embodiment, if the touch panel is reused as the substrate of the polarization module, the phase retardation layer 02 can be combined with the touch panel by naturally attaching or adding the interlayer dielectric layer, because the interlayer dielectric layer is generally made of inorganic insulating material, and the film thickness is between tens of nm and hundreds of nm, which is much less than the thickness of the bonding adhesive layer 01; therefore, the thickness of the display device can be reduced.

In some embodiments, the phase retardation layer can be in direct contact with the touch panel; or an interlayer dielectric layer is arranged between the phase retardation layer and the touch panel. The thickness of the interlayer dielectric layer 05 cannot be not more than 500 nm.

Certainly, a bonding adhesive layer can also be arranged between the phase retardation layer 02 and the touch panel, which are combined through the bonding adhesive layer 01.

Forming a polarization module on the touch panel includes:
directly forming the phase retardation layer on the touch panel; or
forming an interlayer dielectric layer on the touch panel, and forming the phase retardation layer on the interlayer dielectric layer; or
forming a bonding adhesive layer on the touch panel, and forming the phase retardation layer on the bonding adhesive layer.

In the relevant art, the display device further includes the encapsulation film, and the encapsulation film and the polarization module 09, as two independent components, are bonded to the display panel or the touch panel respectively through two bonding processes, which increases the process difficulty and reduces the product yield.

In the embodiment, the integration of the encapsulation film and the polarization module 09 can simplify the bonding process of the display device, improve the product yield, and shorten the production cycle.

In some embodiments, forming the polarization module further includes:
forming an encapsulation film on a side of the linear polarization layer away from the phase retardation layer.

In the embodiment, for the interior of the polarization module 09, the encapsulation film 06 and the linear polarization layer 03 can be combined by naturally attaching or adding the interlayer dielectric layer, because the interlayer dielectric layer is generally made of inorganic insulating material, and the film thickness is between tens of nm and hundreds of nm, which is much less than the thickness of the bonding adhesive layer 01; therefore, the thickness of the polarization module 09 can be reduced, and the flexibility and ultra-thinness of the polarization module 09 can be realized.

Certainly, a bonding adhesive layer 01 can also be arranged between the encapsulation film 06 and the linear polarization layer 03, which are combined through the bonding adhesive layer 01.

In the embodiment, the phase retardation layer 02, the interlayer dielectric layer 05, and the linear polarization layer 03 can be prepared by a coating process; specifically, the phase retardation layer 02 and the linear polarization layer 03 can be made of liquid crystal materials.

In some embodiments, forming the encapsulation film includes:
directly forming the encapsulation film on the linear polarization layer; or
forming an interlayer dielectric layer on the linear polarization layer, and forming the encapsulation film on the interlayer dielectric layer; or
forming a bonding adhesive layer on the linear polarization layer, and forming the encapsulation film on the bonding adhesive layer.

It should be noted that the various embodiments described herein are described in a progressive manner with reference to the same or similar parts throughout the various embodiments, with each embodiment focusing on differences from other embodiments. Especially, for the embodiment, because it is basically similar to the product embodiment, the description is relatively simple, and the relevant information can be referred to some descriptions of the product embodiment.

Unless otherwise defined, technical terms or scientific terms used in the disclosure shall have their ordinary meanings as understood by people with ordinary skills in the field to which the present disclosure belongs. The words “first”, “second” and the like used in the present disclosure do not indicate any order, quantity, or importance, but are only used to distinguish different components. Similar words such as “including” or “containing” mean that the elements or objects appearing before the word cover the elements or objects listed after the word and their equivalents, without excluding other elements or objects. Similar words such as “connected” or “linked” are not limited to physical or mechanical connection, but can include electrical connection, whether direct or indirect. The terms “upper”, “lower”, “left”, “right” and the like are used only to indicate relative positional relationships. When the absolute position of the described object changes, the relative positional relationship can also change correspondingly.

It will be understood that when an element such as a layer, a film, a region, or a substrate is referred to as being “on” or “under” another element, it can be “directly on” or “directly under” the other element or intervening elements can be present.

In the description of the above embodiments, specific features, structures, materials, or characteristics can be combined in any one or more embodiments or examples in a suitable way.

The above is only the specific implementation of the present disclosure, but the protection scope of the present disclosure is not limited to this. Any person skilled in the technical field can easily think of changes or substitutions within the technical scope disclosed in the present disclosure, which should be covered by the protection scope of the present disclosure. Therefore, the scope of protection of the present disclosure should be based on the scope of protection of the claims.

1. A display device, comprising:
a display panel;
a polarization module located on a light-emitting side of the display panel, wherein the polarization module comprises a phase retardation layer and a linear polarization layer arranged in sequence along a direction away from the display panel;
the display panel is reused as a substrate of the polarization module, or a touch panel located between the display panel and the polarization module is reused as the substrate of the polarization module.

2. The display device according to claim 1, wherein
the phase retardation layer is in direct contact with the linear polarization layer; or
an interlayer dielectric layer is arranged between the phase retardation layer and the linear polarization layer; or
a bonding adhesive layer is arranged between the phase retardation layer and the linear polarization layer.

3. The display device according to claim 1, wherein the display panel is reused as the substrate of the polarization module,
the phase retardation layer is in direct contact with the display panel; or
an interlayer dielectric layer is arranged between the phase retardation layer and the display panel; or
a bonding adhesive layer is arranged between the phase retardation layer and the display panel.

4. The display device according to claim 1, wherein the display panel is reused as the substrate of the polarization module, and the display device further comprises:
a touch panel located at a side of the polarization module away from the display panel.

5. The display device according to claim 1, wherein the touch panel is reused as the substrate of the polarization module,
the phase retardation layer is in direct contact with the touch panel; or
an interlayer dielectric layer is arranged between the phase retardation layer and the touch panel; or
a bonding adhesive layer is arranged between the phase retardation layer and the touch panel.

6. The display device according to claim 1, wherein the polarization module further comprises:
an encapsulation film located on a side of the linear polarization layer away from the phase retardation layer.

7. The display device according to claim 6, wherein
the encapsulation film is in direct contact with the linear polarization layer; or
an interlayer dielectric layer is arranged between the encapsulation film and the linear polarization layer; or
a bonding adhesive layer is arranged between the encapsulation film and the linear polarization layer.

8. The display device according to claim 2, wherein the thickness of the interlayer dielectric layer is not more than 500 nm.

9. A method for manufacturing a display device, comprising:
preparing a display panel;
forming a polarization module on the display panel, or forming the polarization module on a touch panel on a light-emitting side of the display panel, wherein the polarization module comprises a phase retardation layer and a linear polarization layer arranged in sequence along a direction away from the touch panel.

10. The method according to claim 9, wherein forming the polarization module comprises:
forming the phase retardation layer, and directly forming the linear polarization layer on the phase retardation layer; or
forming the phase retardation layer, forming an interlayer dielectric layer on the phase retardation layer, and forming the linear polarization layer on the interlayer dielectric layer; or
forming the phase retardation layer, forming a bonding adhesive layer on the phase retardation layer, and forming the linear polarization layer on the bonding adhesive layer.

11. The method according to claim 9, wherein forming a polarization module on the display panel comprises:
forming the phase retardation layer on the display panel directly; or
forming an interlayer dielectric layer on the display panel, and forming the phase retardation layer on the interlayer dielectric layer; or
forming a bonding adhesive layer on the display panel, and forming the phase retardation layer on the bonding adhesive layer.

12. The method according to claim 9, wherein forming a polarization module on the touch panel comprises:
forming the phase retardation layer on the touch panel directly; or
forming an interlayer dielectric layer on the touch panel, and forming the phase retardation layer on the interlayer dielectric layer; or
forming a bonding adhesive layer on the touch panel, and forming the phase retardation layer on the bonding adhesive layer.

13. The method according to claim 9, wherein forming the polarization module further comprises:
forming an encapsulation film on a side of the linear polarization layer away from the phase retardation layer.

14. The method according to claim 13, wherein forming the encapsulation film comprises:
forming the encapsulation film on the linear polarization layer directly; or
forming an interlayer dielectric layer on the linear polarization layer, and forming the encapsulation film on the interlayer dielectric layer; or
forming a bonding adhesive layer on the linear polarization layer, and forming the encapsulation film on the bonding adhesive layer.

15. The method according to claim 9, wherein the phase retardation layer and the linear polarization layer are made of liquid crystal material.

16. The method according to claim 10, wherein the phase retardation layer and the linear polarization layer are made of liquid crystal material.

17. The method according to claim 10, wherein the interlayer dielectric layer is made of inorganic insulating material.

18. The method according to claim 17, wherein the phase retardation layer, the interlayer dielectric layer, and the linear polarization layer are prepared by coating process.

19. The display device according to claim 3, wherein the thickness of the interlayer dielectric layer is not more than 500 nm.

20. The display device according to claim 7, wherein the thickness of the interlayer dielectric layer is not more than 500 nm.
